(19) United States
(12) Patent Application Publication
(10) Pub. No.: US 2014/0292347 A1
(43) Pub. Date: Oct. 2, 2014

(54) Low Cost Circuit to Detect Faults of ISC Outputs and/or HV Bus Shorted to Chassis

(71) Applicant: Lihua Chen, Northville, MI (US)

(72) Inventor: Lihua Chen, Northville, MI (US)

(73) Assignee: FORD GLOBAL TECHNOLOGIES, LLC, Dearborn, MI (US)

(21) Appl. No.: 13/851,439

(22) Filed: Mar. 27, 2013

(51) Int. Cl. G01R 31/02; G01R 31/00

(52) U.S. Cl. CPC G01R 31/025; G01R 31/006
USPC 324/509

(57) ABSTRACT

A low cost fault detection and protection method and embodiment circuit can detect short circuit faults between an inverter system control (ISC) circuit outputs and a chassis, an electrical machine winding and a chassis, and a DC bus and a chassis. A fault protection unit (FPU) can monitor chassis voltage with respect to a DC bus to detect the presence of a short circuit fault, and provide status output indication of whether a fault is detected. By way of example, an FPU can include a window detector and a signal transmitter. An FPU can provide status output to an ISC controller configured to terminate ISC operation when any of the aformentioned faults is present, thereby preventing damage to devices contained in the ISC circuit.

### BACKGROUND OF INVENTION

1. Field of Art

This invention pertains generally to fault detection circuits, and more particularly to fault detection circuits for vehicle electric drive systems.

2. Background Art

Electrified vehicles reduce fossil fuel consumption and atmospheric emissions by employing an electric drive system to assist or replace an internal combustion engine. In general, an electric drive system consists of an energy source, an energy conversion system, and an electric machine powered by the energy conversion system and configured to drive a load. Typically, the energy source is in the form of an energy storage device, such as a high voltage battery. Generally, the energy conversion system includes an inverter system control (ISC) configured to receive a DC voltage from the battery and provide alternating phase currents to the electric machine, for example to an electric motor configured to drive a wheel set for an electrified vehicle.

The ISC can be connected to a high voltage battery by high voltage DC positive and negative rails, and can be grounded by directly mounting it on a vehicle chassis. In many configurations, an ISC can include Y-capacitors to improve ISC noise immunity and stabilize voltage fluctuations that can occur during normal ISC operation. However, faults and irregularities can occur that can lead to large erratic voltage swings at the DC rails. For example, ISC output cable isolation may become compromised or motor and/or generator winding isolation may break down. Alternatively, an ISC output or DC rail may inadvertently be shorted to the chassis during testing or servicing. In any of the above cases, the chassis voltage with respect to a DC rail can change quickly and dramatically, generating a large common mode current. If not addressed quickly, the common mode current can damage ISC control devices as well as other modules directly coupled to the DC bus.

### SUMMARY OF INVENTION

An effective and economical circuit for fault detection and protection is presented. An example circuit can include an energy storage device (ESD); an inverter system control (ISC) circuit having a positive direct current (DC) bus and a negative DC bus coupled to the ESD; and a fault protection unit (FPU) configured to monitor a chassis voltage with respect to one of the DC buses. In an example embodiment, the ISC circuit can be coupled to the chassis and at least one electric machine, such as a motor or a generator. An FPU can be configured to use the chassis voltage with respect to a DC bus to check for the presence of a ground fault, and can be configured to provide output that indicates whether a ground fault is detected. For example, when the chassis voltage with respect to a DC bus falls within a predetermined range typical of normal operation, an FPU can provide a “no fault” status signal that indicates that no fault is detected. Conversely, when the potential difference is outside the predetermined range, an FPU can provide a fault signal that indicates that a fault is present. In an example embodiment, an FPU can be coupled to an ISC controller configured to halt ISC operation when a ground fault is detected in order to prevent damage to components such as the ISC power electronic devices, the ISC controller area network (CAN) controller, or other devices. A system or circuit of the invention can be configured to detect a ground fault between the chassis and an ISC output, between the chassis and a DC rail, or between the chassis and an electrical machine winding.

An example FPU can comprise a fault detection module (FDM) configured to monitor a chassis voltage with respect to a DC bus and use that voltage to determine whether a ground fault exists. In addition, an FPU and can be configured to provide output that indicates whether a ground fault is present. In an example embodiment, an FPU can be configured to determine whether the chassis voltage with respect to a DC bus lies within a predetermined range. By way of example, an FDM can comprise a window detector that can include a first comparator configured to compare an input to a first voltage reference, and a second comparator configured to compare the input to a second voltage reference. In an example embodiment, the first and second voltage references can represent lower and upper bounds that define a predetermined range. An input signal outside the predetermined range can indicate a ground fault, while an input voltage within the predetermined range can indicate normal operation. In an example embodiment, an FPU can include a status output module (SOM) configured to receive FDM output and provide status output. By way of example, an SOM can comprise a signal transmitter such as an opto-coupler or other device configured to provide electrical isolation between its input and output such as isolation signal transformer. An FPU can be configured to provide output that can indicate either normal operation or the presence of a fault.

A method of the invention can include monitoring a chassis voltage with respect to a DC bus rail, using said chassis voltage to determine whether a fault is present, and providing a status output that indicates whether a ground fault is present. In an example method, using the chassis voltage with respect to a DC bus to determine whether a fault is present can comprise determining whether the chassis voltage with respect to a DC bus is within a predetermined range. By way of example, a method can include providing status output to an ISC controller configured to stop ISC operation when a fault is detected so that damage to circuit or system components can be prevented.

### BRIEF DESCRIPTION OF THE DRAWINGS

FIG. 1 shows an example system configured to provide ground fault detection and protection.

FIG. 2 shows an example system configured to provide ground fault detection and protection.

FIG. 3 shows an example circuit for providing fault detection and protection.

FIG. 4 shows a flow diagram of an example method for fault detection and protection.

FIG. 5 shows an example circuit in which an FPU can detect an ISC output fault when a lower ISC switch is conducting.

FIG. 6 shows an example circuit in which an FPU can detect an ISC output fault when an upper ISC switch is conducting.

FIG. 7 shows an example circuit in which an FPU can detect a positive DC bus fault.

FIG. 8 shows an example circuit in which an FFPU can detect a negative DC bus fault.

### DETAILED DESCRIPTION OF EXEMPLARY EMBODIMENTS

As required, example embodiments of the present invention are disclosed. The various embodiments are meant to be non-limiting examples of various ways of implementing the invention, and it is understood that the invention may be embodied in alternative forms. The present invention will be described more fully hereinafter with reference to the accompanying drawings in which like numerals represent like elements throughout the several figures, and in which example embodiments are shown. The figures are not necessarily drawn to scale and some features may be exaggerated or minimized to show details of particular elements, while related elements may have been eliminated to prevent obscuring novel aspects. The specific structural and functional details disclosed herein should not be interpreted as limiting, but merely as a basis for the claims and as a representative basis for teaching one skilled in the art to variously employ the present invention. For example, while the exemplary embodiments are discussed in the context of a vehicle, it will be understood that the present invention need not be limited to that particular arrangement. Furthermore, control functions described as performed by a single module, can in some instances, be distributed among a plurality of modules. In addition, methods having actions described in a particular sequence may be performed in an alternate sequence without departing from the scope of the appended claims.

In general, electric drive power trains for electrified vehicles are designed with DC bus isolation and common node noise protection for components. However, operator and/or technician mistakes, damage to system components, or deterioration of isolation/insulation for ISC outputs and electrical machine windings can lead to ground faults, such as short circuits to the vehicle chassis. Components coupled to a DC bus or grounded by the chassis can be significantly damaged by such faults. Accordingly, a system for ground fault detection and protection is presented that is fast, reliable and economical.

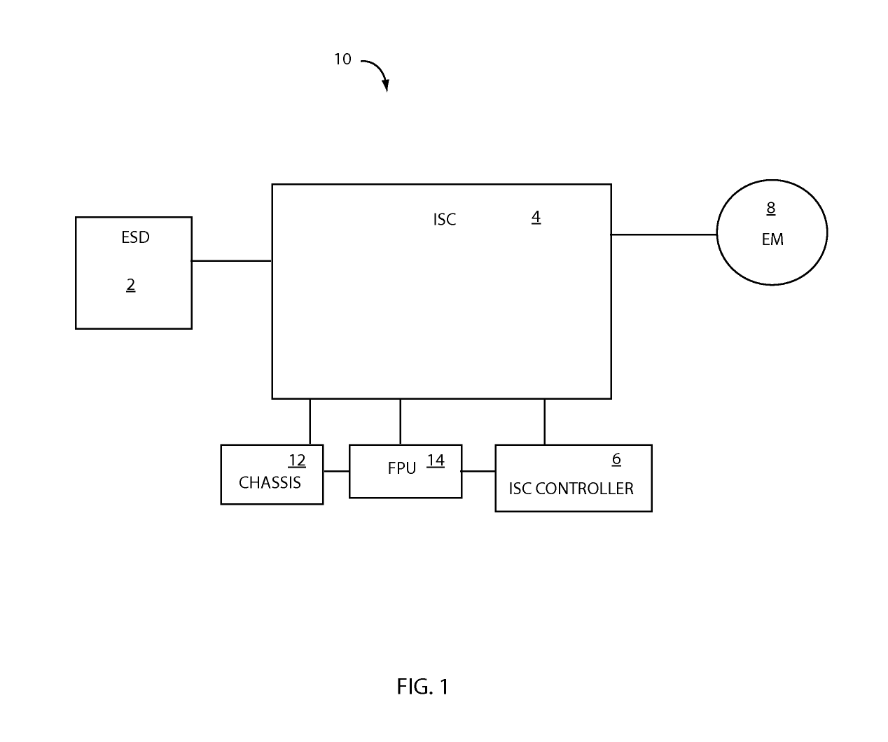

Turning to the Drawings, wherein like reference numerals refer to like elements throughout, FIG. 1 shows a system 10 that includes an energy storage device (ESD) 2 coupled to an inverter system control (ISC) 4 controlled by an ISC controller 6. The ISC 4 can be coupled to at least one electric machine, such as electric machine (EM) 8, and can be configured to transfer energy between the EM 8 and the ESD 2. In an example embodiment, the ISC 4 can be coupled to a chassis 12, for example, the ISC 14 can be mounted to a chassis for an electrified vehicle. A fault protection unit (FPU) 14, coupled to the ISC 4 and to the vehicle chassis 12, can be configured to provide status output to the controller 16. For example, the FPU 14 can provide a fault signal when a ground fault is detected. In an example embodiment, the ISC controller 6 can be configured to shut down ISC 4 operation in response to receiving a fault signal from the FPU 14.

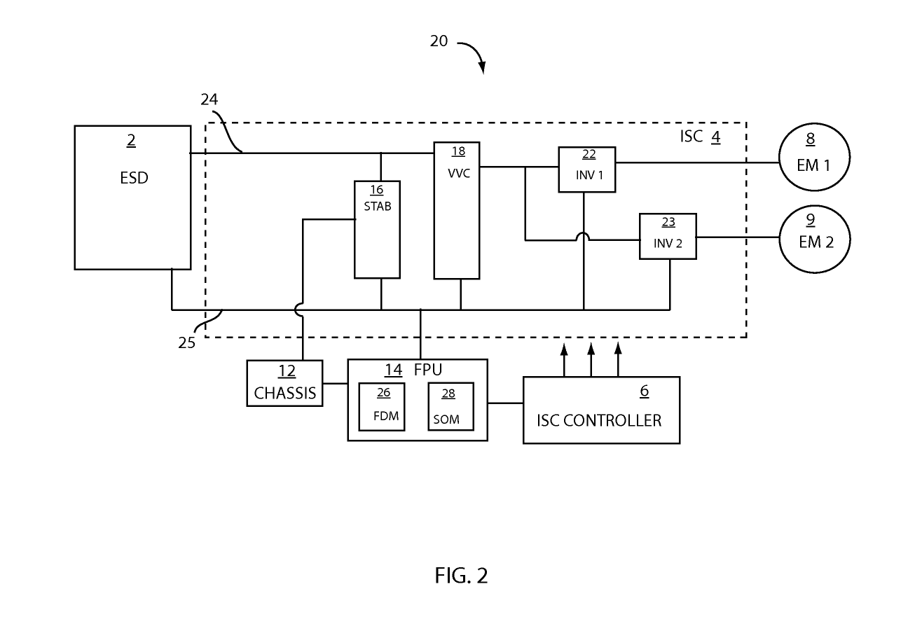

FIG. 2 shows an example system 20 for fault detection and protection. In the system 20, the ISC 4 is coupled to the EM 8 as well as to a second machine, EM 9. In an example embodiment, each of EMs 8, 9 can be embodied as a permanent magnet synchronous motor (PMSM) that can be configured to operate as a motor and/or a generator. By way of example, the EM 8 can be configured to operate as a motor to drive a wheel set (not shown) for an electric vehicle, and the EM 9 can be configured to operate as a generator. The ISC 4 can be configured to use a DC voltage provided by the ESD 2 to provide alternating phase current to the EM 8, and can convert alternating current received from the EM 9 to DC energy to charge the ESD 2. By way of example, the ESD 2 can be in the form of a high voltage traction battery for an electrified vehicle, such as a 300V lithium ion battery or NIMH battery. Although discussed herein in terms of a system using a high voltage battery, it is contemplated that other types of energy storage devices can be used in lieu of a battery, such as, but not limited to, a capacitor, a capacitor bank, or other electric power sources.

By way of example, the ISC 4 can include a stabilizing portion 16, a variable voltage converter (WC) portion 18, a first inverter 22 and a second inverter 23. In an example embodiment, the stabilizing portion 16 can be disposed between a positive DC bus 24 and a negative DC bus 25, and can be coupled to a chassis 22, which in an example system, can be embodied as a chassis for an electric vehicle. The stabilizing portion 16 can be configured to stabilize some voltage fluctuations as well as improve ISC 4 noise immunity.

The WC portion 18 can be configured for both boost and buck operation. For example, the WC portion 18 can be configured to boost an ESD 2 voltage to provide a higher voltage to the first inverter 22, which can be configured to provide alternating phase currents to the EM 8. In addition, the WC portion 18 can be configured to reduce a higher voltage provided by the inverter 23 to provide a lower charging voltage for the ESD 2.

The FPU 14 can be configured to monitor the chassis voltage with respect to a DC bus (V_{CH-DC}) and provide a status output that indicates whether a ground fault is detected. In the example system 20, the FPU 14 is coupled to the chassis 12 and the negative DC bus 25, and is configured to monitor the voltage difference between the two. By way of example, the FPU 14 can comprise a fault detection module (FDM) 26 configured to monitor V_{CH-DC} and use V_{CH-DC} to check for the presence of a ground fault. In an example embodiment, the FDM 26 can be configured to determine whether (V_{CH-DC}) has a value typically expected during normal operating conditions. V_{CH-DC} values that significantly differ from expected values, or changes in V_{CH-DC} that are greater than typical voltage fluctuations, can indicate the presence of a ground fault. By way of example, the FDM 26 can be configured to compare V_{CH-DC} to at least one reference voltage to determine whether a fault exists. Depending on a circuit's configuration, the relationship of V_{CH-DC} with respect to a reference voltage can indicate a fault condition. By way of example, but not limitation, V_{CH-DC} can be compared to an upper reference defining an upper bound for a normal or non-fault operation range, and/or a lower reference defining a lower bound for a normal or non-fault operation range. In this type of configuration, a V_{CH-DC} that exceeds the upper reference or falls below the lower reference can indicate that a ground fault is present. In other words, fault detection can be performed by detecting that a V_{CH-DC} is outside a predetermined range. The FDM 26 can comprise hardware, software, firmware, or some combination thereof to effectively implement its fault detection functionality.

As shown in the example system 20, the FPU 14 can also comprise a status output module (SOM) 28 configured to provide status output that indicates whether a ground fault is detected. For example, the SOM can be configured to provide a fault signal when a fault is detected, and a “no-fault” or “normal operation” signal when no fault is detected. In a further embodiment, the SOM can be configured to provide a fault signal when a fault is detected by the FDM 26, and no output when the system 20 is operating normally with no short circuits detected. The SOM 28 can be configured to provide output to the ISO controller 6 that can be configured to shut down operation of the ISO 14 when a ground fault is detected by the FDM 26.

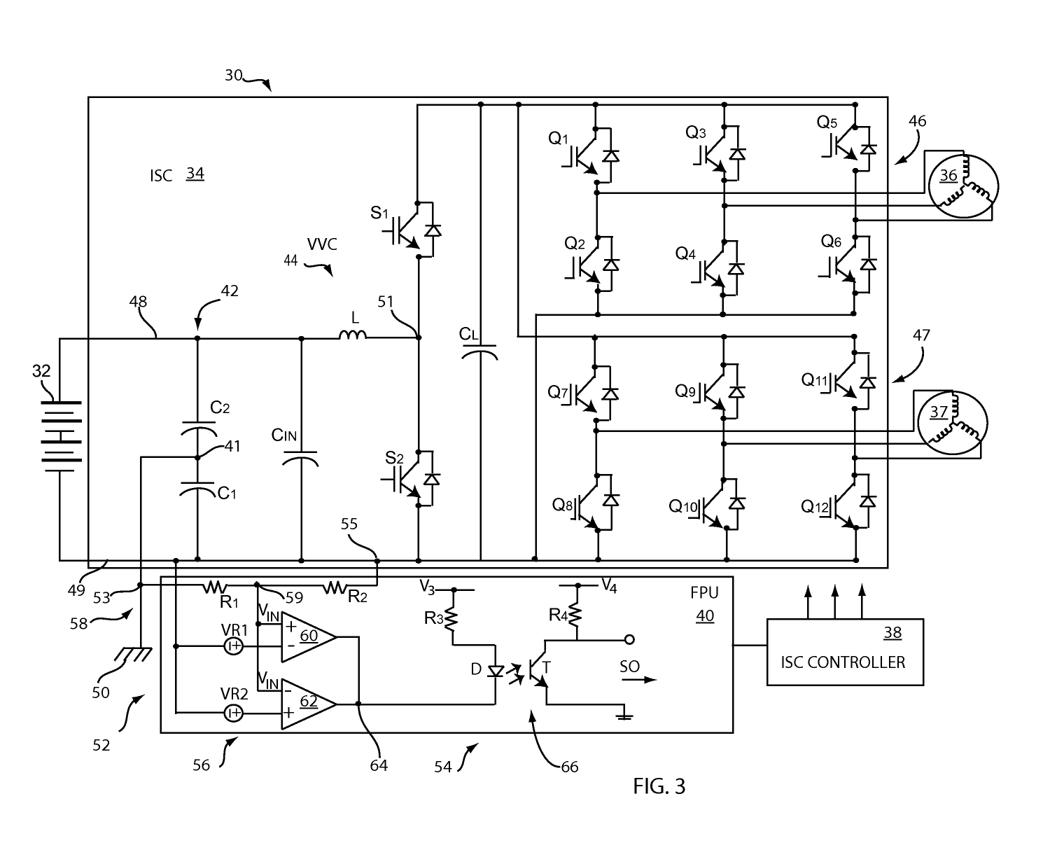

FIG. 3 shows an example circuit 30 for practicing the invention. The circuit 30 includes an ESD 32 coupled to an ISO circuit 34, which in turn is coupled to a first EM 36 and a second EM 37. The ISO circuit 34 is also coupled to an ISO controller 38 configured to control ISO circuit 34 operation. A fault protection unit (FPU) 40 is coupled to the ISO circuit 34. The FPU 40 is configured to determine whether a ground fault exists, and to provide status output that indicates results of that determination. The FPU 40 can be configured to provide status output to the ISO controller 38, which can be configured to shut down ISO circuit 34 operation in response to receiving a fault signal from the FPU 40.

By way of example, but not limitation, the ESD 32 can be embodied as a high voltage battery for an electrified vehicle. The ISO circuit 34 can include a Y-capacitor branch 42, a WC 44, a first inverter 46 and a second inverter 47. The Y-capacitor branch 42, which can comprise capacitors C1 and C2 arranged in series, can be disposed between a positive DC bus 48 and a negative DC bus 49, and can be configured to provide some degree of voltage stability and noise suppression for the ISO circuit 34 via its connection with a chassis 50 through the node 41. In an exemplary embodiment, the chassis 50 can be embodied as a chassis for an electrified vehicle and the ISO circuit 34 can be mounted thereto.

The WC 44, which can be configured for both boost and buck operation, can comprise an input capacitor O_{N}, an inductor L, a first switching device S₁ and a second switching device S₂. The input capacitor C_{IN} can be disposed between, and coupled to, the positive DC bus 48 and the negative DC bus 49. The inductor L can be disposed at the positive DC bus 48 and coupled to the switches S₁ and S₂ at a node 51.By way of example, but not limitation, the switching devices S₁ and S2 can comprise metal-oxide-semiconductor field-effect-transistors (MOSFETs),insulated gate bipolar transistors (IGBTs), or the like.

A linking capacitor C_{L} can be disposed between the WC 44 and the inverters 46 and 47. In an example embodiment, the inverter 46 can receive a DC voltage from the WC 44, and, through controlled operation of switches Q1-Q6, provide alternating phase currents to the EM 36, which can be in the form of a motor configured to drive a load. In an example embodiment, the EM 36 is configured to drive a wheel set (not shown) of an electrical vehicle. In an example embodiment, the EM 37 is configured to operate as a generator, providing ac current to the inverter 37. The switches Q7-Q12 of the inverter 47 can be individually controlled to convert ac current received from the EM 37 to a DC voltage that can be provided to the WC 44. In an example embodiment, the switches Q1-Q12 are power electronic devices such as MOSFETs, IGBTs, or other suitable devices, and can be independently driven by the ISC controller 38. By way of example, pulse width modulation can be used to independently turn the switches Q1-Q12 on and off to implement various duty cycles for effective operation of the inverters 46 and 47.

The FPU 40, coupled to the chassis 50 at node 53 and to the ISC circuit 34 at node 55, can include an FDM 52 and a SOM 54. The FDM 52 is configured to monitor the chassis 50 voltage with respect to a DC bus (V_{CH-DC}), in this case with respect to the negative DC bus 49, and use V_{CH-DC} to determine whether a ground fault exists. The SOM 54 can be configured to provide output indicating the result of that determination. By way of example, but not limitation, the SOM 54 can provide a fault signal when a ground fault is detected, and provide a no-fault signal when no ground fault is detected.

In the example circuit 40, the FDM 52 comprises a window detector 56 configured to detect large changes in the chassis voltage relative to the DC bus 49 (V_{CH-DC}). The window detector 56 can achieve this by determining whether an input voltage V_{IN}, lies within a predetermined range. By way of example, the window detector 56 can comprise a first comparator 60 configured to compare an input voltage V_{IN} to a first reference voltage V_{R1}, and can further comprise a second comparator 62 configured to compare the input V_{IN} to a second reference voltage V_{R2}. In an example embodiment, the window detector 56 can be configured to detect when V_{R1}<V_{IN}<V_{R2} Thus, the window detector 56 can detect large changes in V_{CH-DC} that result when a short circuit to the chassis 50 occurs and cause V_{CH-DC} to fall outside a predetermined range. In an example circuit, the comparator 60 can be configured to provide a high output when V_{IN} is higher than V_{R1}, and can be configured to provide a low output when V_{IN} is lower than V_{R1}. The second comparator 62 can be configured to provide a high output when V_{IN} is lower than V_{R2}, and can be configured to provide a low output when V_{IN} is greater than V_{R2}. Thus, the window detector 56 output, i.e. the voltage at node 64, can be high when V_{IN} is within the predetermined range bounded by V_{R1} and V_{R2}, and low when V_{IN} is outside the predetermined range.

In an example embodiment, V_{IN} comprises the chassis 50 voltage relative to the negative DC bus 49, i.e. V_{CH-DC}. As shown in FIG. 3, the FPU 40 can include a voltage divider portion 58 configured to attenuate the DC bus potential to provide a lower voltage input to the window detector 56. The voltage divider portion can be included for both practical and safety reasons. The voltage divider portion 58 can comprise a resistor R₁ connected in series with a resistor R₂. The voltage at a node 59, disposed between R₁ and R₂, can provide the input voltage V_{IN} for the window detector 56. It is noted that for the purposes of this disclosure, the chassis voltage with respect to a DC bus, V_{CH-DC}, can refer to the difference between a chassis potential and an actual DC bus potential, and can also be used to refer to a chassis potential with respect to a DC bus potential attenuated by a voltage divider circuit. The reference voltages V_{R1}, V_{R2} can be designated as necessary for a particular circuit configuration to enable a determination as to whether a chassis voltage with respect to a DC bus voltage lies within or outside a predetermined range of voltages that can effectively indicate whether a ground fault condition exists. Under normal operating conditions, the difference in potential between a chassis and a DC negative bus is generally around ½ the traction battery voltage. Accordingly, the FDM 52 can be configured to determine whether V_{CH-DC} lies within a predetermined range of values above and below ½ the ESD 32 voltage (V_{ESD}). Ground faults to a chassis can cause V_{CH-DC} to experience a voltage swing of around ½ V_{ESD}. Accordingly, in an example embodiment, V_{R1} can be set at ¼ V_{ESD}, and V_{R2} can be set at ¾ V_{ESD} to enable the window detector 56 to detect large swings in voltage indicative of a short circuit to the chassis 50. In an exemplary embodiment, the FPU 40 can be configured to detect a ground fault within 10 μsec, or less than half a typical inverter switching cycle.

In an example embodiment, the SOM 54 can comprise a signal transmitter, which can, for example be embodied as a signal transmitter configured for electrical isolation between its input and output. In an example embodiment, the SOM 54 is embodied as a signal transmitter comprising an opto-coupler 66 coupled to a voltage supply V3 through a resistor R₃ and a voltage supply V₄ through a resistor R₄. The voltage supplies V₃ and V₄ can be arranged so that they are isolated from each other and do not share a common ground. The opto-coupler 66 can comprise a LED diode D that does not conduct when the window detector 56 is high. Thus, in an example circuit, a status output (SO) signal can be high when the window detector 56 output is high. If the window detector 56 output is high for normal operation, then a high SO can indicate that no ground fault detected. In this arrangement, a low voltage at node 64 will indicate that V_{CH-DC} is not within a predetermined range characteristic of normal operation, and the LED diode D will conduct. This will cause the SOM 54 output SO to be low, providing a fault signal that indicates the presence of a ground fault.

In an example embodiment, an SO output can be provided to the ISC controller 38. The ISC controller 38 can be configured to terminate ISC circuit 34 operation in response to receiving a fault signal from the FPU 40. In addition, in an example embodiment, the ISC controller 38 can be configured to provide a fault signal to a vehicle control system (VCS) configured to open contactors (not shown) that couple the ESD 32 to the ISC 34 to prevent further energizing of the DC rails 48, 49.

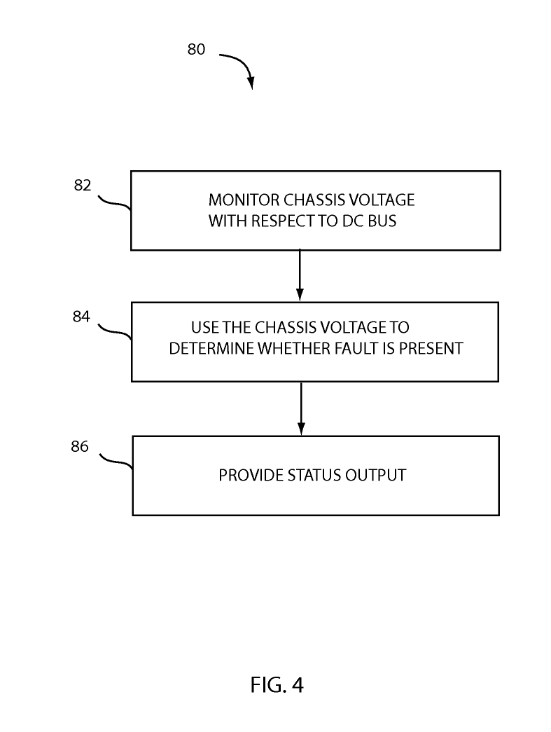

FIG. 4 shows an example method 80 for detecting a ground fault. At block 82, a chassis voltage with respect to a DC bus can be monitored. For example, referring to FIG. 3, the FDM 50 can receive DC bus voltage input via its connection with the negative DC bus 49 at the node 55, and receive chassis voltage input via its connection with the chassis 50 at the node 53. The voltage at the node 59 can provide the potential at the chassis 50 with respect to the DC bus 49 (V_{CH-DC}).

At block 84, the chassis voltage with respect to the DC bus can be used to determine whether a ground fault is present. This determination can be made in various ways, as will occur to those skilled in the art. By way of example, referring to FIG. 3, V_{CH-DC} can be rece_{ived} at the window detector 56 configured to compare it to voltage references VR1 and VR2. When V_{CH-DC} falls within the range bounded by V_{R1} and V_{R2}, a high output from the window detector 56 indicates that no fault is present. However, if V_{CH-DC} fails to fall within the range bounded by V_{R1} and V_{R2}, a low output from window detector 56 indicates detection of a ground fault. The method 80 can continue at block 86 at which status output can be provided that indicates whether a fault is detected. Block 86 can be implemented in a variety of ways. For example, providing status output can comprise an FDM providing output regarding its determination as to whether a ground fault exists. For example, the window detector 56 can provide output at node 64 as to whether V_{CH-DC} is within a predetermined range: a low output indicating a fault condition, and a high output indicating a no-fault condition. Thus, providing output can simply comprise providing an FDM fault check result at an FPU, and need not include providing output external to the FPU. For example, an FPU can be configured to only provide output when a fault exists; with the absence of output indicating that no fault is detected.

However, in an example method, providing status output can include providing FDM output to an SOM, and an SOM providing status output. For example, window detector 56 output at node 64 can be provided as input to the SOM 54, which can comprise the signal transmitter 66. A high output from the window detector 56 at node 64 can be provided to the signal transmitter 54 which can output a high signal that indicates normal operation, or no fault detection. Similarly, when a short circuit or ground fault is detected, a low output from the window detector 56 can be provided to the signal transmitter 66 which can output a low “fault” signal. Output from the SOM 54 can be provided to the ISO controller 38. As discussed above, it is also contemplated that an SOM can be configured to transmit a fault signal under fault conditions, but provide no output under normal operating conditions, with the absence of a fault signal indicative of normal operation. Alternatively, an FPU can be configured to provide output when a system is operating normally, but provide no output under fault conditions. In this scenario, the absence of output can be interpreted as a fault signal.

Including an SOM at an FPU enables the use of a transmitting device that can enhance signal quality. By selecting a transmitting device in the form of an opto-coupler, transformer or other similar device configured to provide electrical isolation between its input and output, noise can be reduced and circuit performance improved. It is noted that an SOM, as well as an FDM, can be embodied and implemented in various ways to provide status output. While described herein by examples in which output comprising a low signal indicates the presence of a fault and output comprising a high signal indicates normal operation, it is understood that other configurations can be used; such as providing a high signal for a fault and a low signal for normal operation, or the absence of a signal as a fault or no-fault indication.

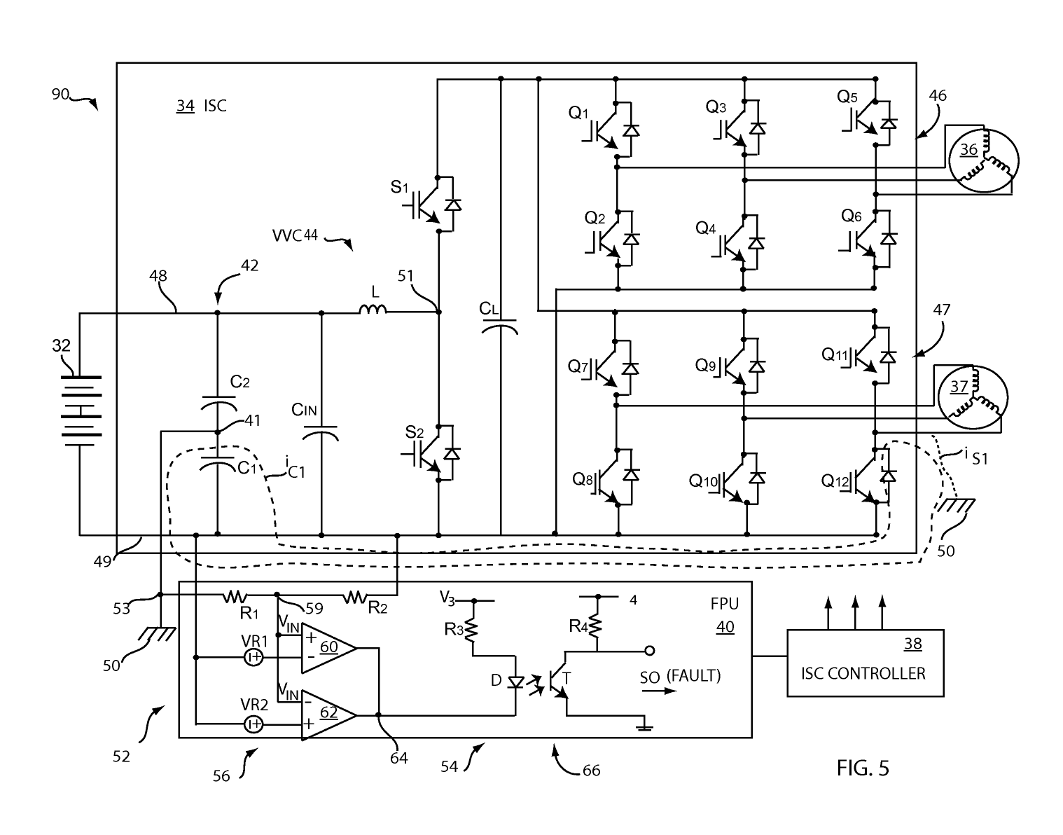

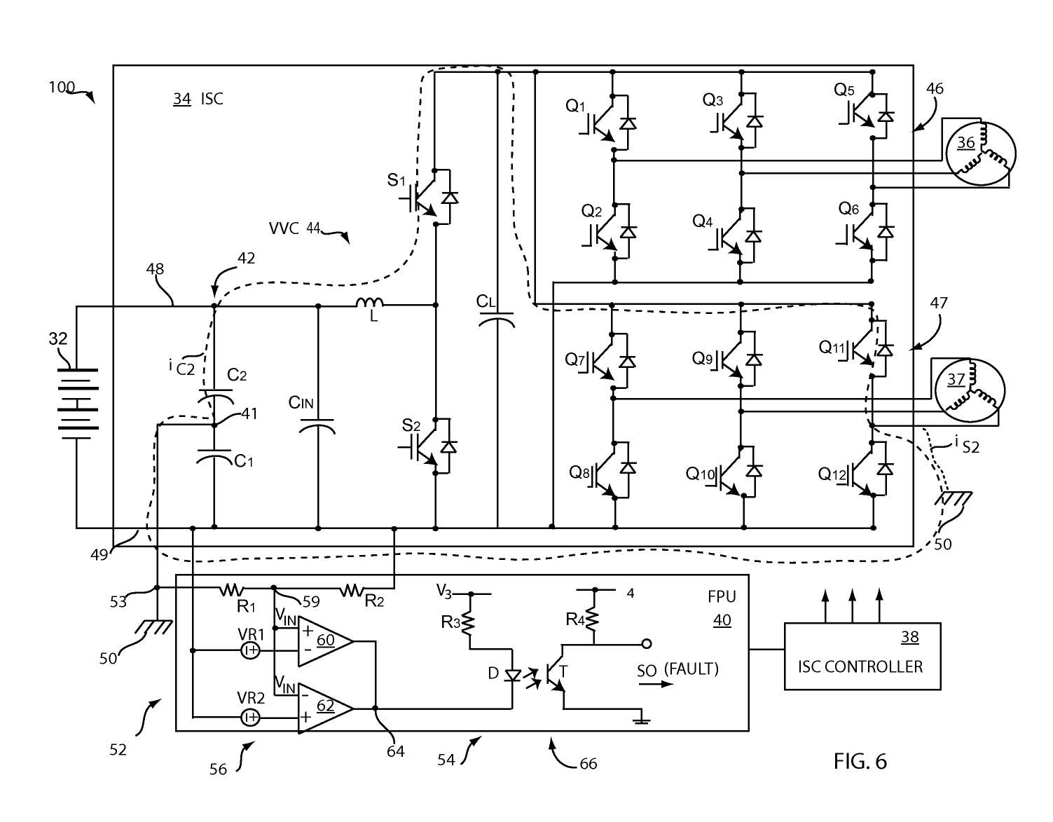

FIGS. 5 and 6 show example circuits 90, 100 in which an FPU can detect that an ISC output is in contact with the chassis. Large fluctuations in the potential difference between the DC bus and the chassis can occur as upper and lower ISC switches are turned on and off during short circuit conditions. These fluctuations can cause a common mode current Icm to flow due the distributed parasitic capacitance C of the ISC 34, where Icm=C dv/dt. ISC controller devices with limited common mode rejection capability can be damaged within seconds by a common mode current. For example, in circuits without an FPU, ISC CAN receivers have failed during hardware testing procedures when an ISC output is inadvertently shorted to a chassis. While some ISC circuits can be designed with IGBT fault detection capability, those circuits are typically unable to effectively detect an ISC output short to the chassis due to a relatively very low fault current, typically around 10A, which can be much lower than the IGBT fault protection threshold current, typically on the order of hundreds of amperes.

An FPU can quickly detect and report the presence of a short circuit to protect ISC and ISC controller components. Because an FPU can detect the presence of an ISC fault in around 10 μs, less than half the typical ISC switching cycle, and quickly provide a fault signal to an ISC controller, ISC operation can be shut down before the ISC is subjected to the large voltage fluctuations that can result when a chassis short is present and a presently conducting device is switched off and a different device is switched on.

FIG. 5 shows the example circuit 90 having an ISC circuit 34 output shorted to the chassis 50 while a lower switch Q12 of the inverter 37 is conducting. The short circuit i_{S1} can cause current to circulate in a loop i_{C1}. In this scenario, the capacitor C₁ can be discharged by the i_{C1} current loop, which can cause the voltage potential between the negative DC bus 49 and the chassis 50 to undergo a large negative swing of around half the ESD 32 voltage (V_{ESD}). As discussed earlier herein, under normal operating conditions, the voltage difference between the chassis 50 and the DC bus 49 is expected to be around ½ V_{ESD} , within the predetermined range of the window detector 56 having a V_{R1} of around ¼ V_{ESD} and V_{R2} of around ¾ V_{ESD}. However, in the scenario depicted in FIG. 5, the chassis 50 potential with respect to the DC bus 49 can experience a significant negative swing of around half V_{ESD} due to the current i_{C1}, causing it to fall below the V_{R1} threshold. Accordingly, the voltage V_{CH-DC} will no longer fall within predetermined range of the window detector 56. As a result, the FPU 40 will output a fault signal. In an example embodiment, the fault signal can be provided to the ISC controller 38 which can be configured to shut down operation of the ISC circuit 34 in response, thereby protecting by the ISC circuit 34 and other modules or devices coupled to the DC bus 49.

FIG. 6 shows the example circuit 100 in which an ISC output is shorted to the chassis 50 (i_{S2}) and the upper switch Q₁₁ is turned on and is conducting. In this case, a current will circulate in the loop i_{C2}. The capacitor C₂ can be discharged, which can cause a significant change in the potential between the DC bus 49 and the chassis 50 in a positive direction of about half V_{ESD}. The significant voltage swing will push the input signal V_{IN} (V_{CH-DC}) outside the predetermined range of the window detector 56. Accordingly, the FPU 40 will output a fault signal. Because the FPU 40 can detect the short within a few microseconds, the ISC controller 38 can receive an FPU fault signal and shut down ISC 34 operation prior to turning switch Q11 off and turning switch Q12 on.

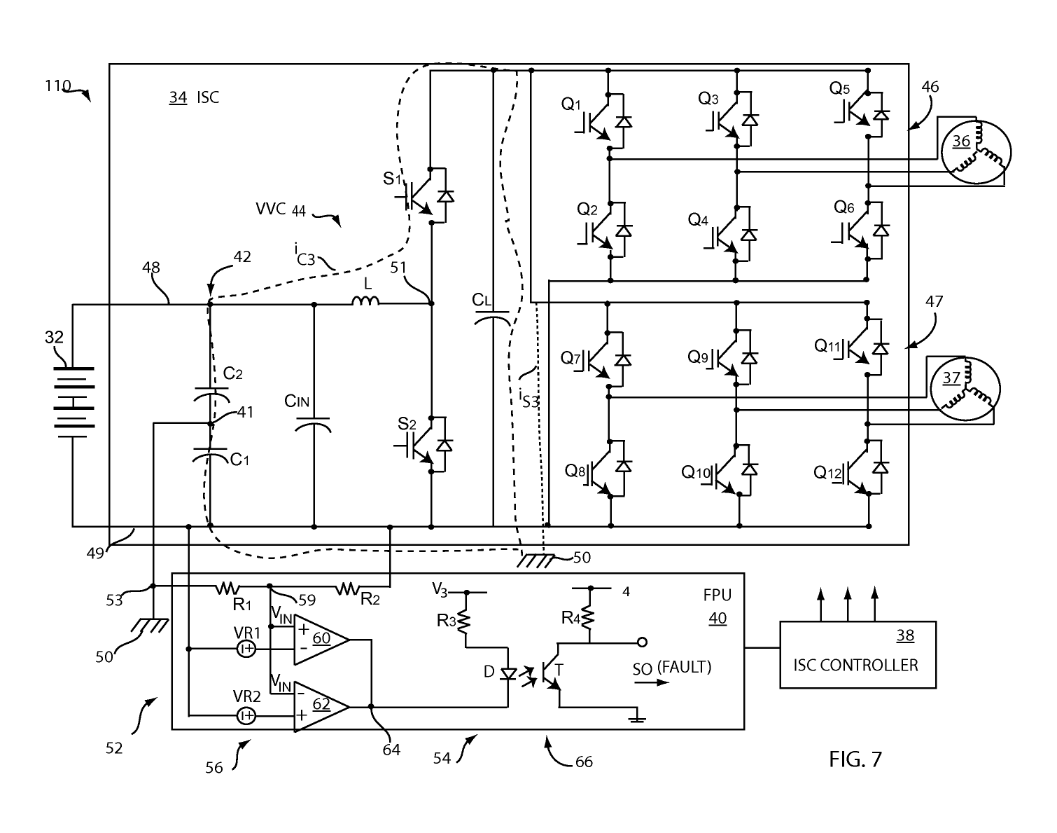

FIGS. 5 and 6 illustrate examples in which an FPU can detect a short circuit between an ISC circuit output and a chassis. However, an FPU can detect other types of short circuits as well, including short circuits between an ISC positive or negative HV bus and a chassis, and short circuits between a motor or generator winding and the chassis. FIG. 7 shows an example circuit 110 in which an FPU can detect a short circuit i_{S3} between the positive DC bus 58 and the chassis 50. The short circuit i_{S3} causes a current to flow in a path i_{C3}. As a result, there will be a large change in the chassis 50 potential with respect to the negative DC bus 49, with V_{CH-DC} exceeding ¾ V_{ESD}. The window detector will detect the large change in potential because V_{CH-DC} will no longer fall within the predetermined range defined by V_{R1} and V_{R2}. Thus, the FDM 52 provides output that indicates a fault is detected, in this example a low signal at node 64. Accordingly, the SOM 54 outputs a fault signal.

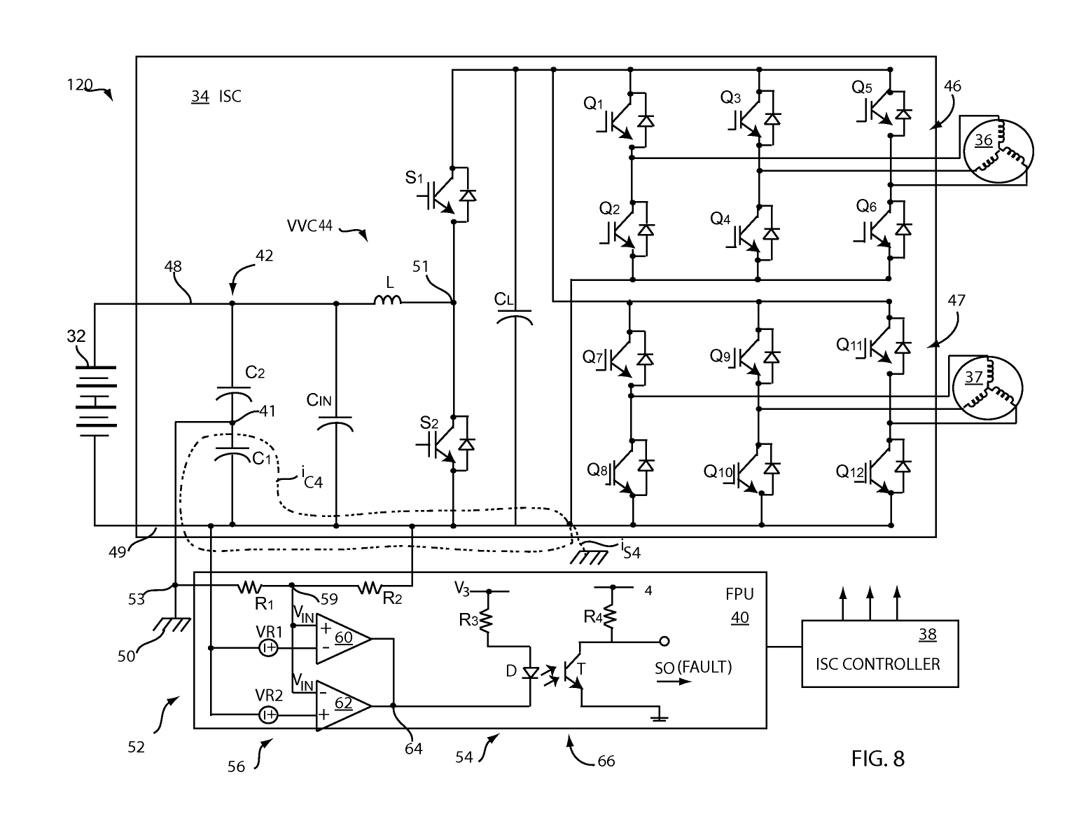

FIG. 8 depicts a circuit 120 having a short circuit i_{S4} between a negative DC bus and a chassis. The short circuit generates a current loop i_{C4}. In this scenario, the difference between the chassis 50 potential and the negative DC bus 49 potential is essentially zero. Because V_{CH-DC} is less than V_{R1} (set at ¼ V_{ESD}) the window detector 56 will detect the large change in chassis voltage as V_{CH-DC} will not fall within range defined by V_{R1} and V_{R2}, and provide a low output at node 64. Again, the signal transmitter 66 will output a fault signal.

In an example embodiment, FPU 40 output can be provided to the ISC controller 38 which can shut down ISC circuit 34 operation. In addition the ISC controller 38 can in turn provide a fault signal to a vehicle control system (VCS) configured to shut down traction battery or ESD operation under fault conditions to prevent problems and/or failures with an electric drive system. However, it is contemplated that an example circuit can include transmission of a fault signal directly from the FPU 40 to a VCS or other control module in addition to or in lieu of ISC controller 38.

Thus the invention provides a system and apparatus for quick, reliable and economical ground fault detection. An FPU can monitor the potential between a chassis and a DC bus to detect the presence of a ground fault, and provide output that indicates whether a ground fault is present. In an example embodiment, an FPU can be used at an electric vehicle to detect ground faults associated with its electric drive system, such as ground faults between a vehicle chassis and a DC bus, between the chassis and an ISC output, and between the chassis and an electric machine output. By way of example, status output can be provided to an ISC controller that can shut down ISC operation when a fault is detected to protect electronic devices coupled to the ISC. In an example embodiment, an FPU can comprise a window detector configured to detect large voltage changes that can result from a short circuit to a chassis. Configured for quick detection of ground faults, an FPU can enable ISC shutdown prior to completion of a switching cycle, preventing significantly large voltage swings on the DC buses. While other fault detection schemes may be expensive or difficult to implement, an FPU can be implemented easily and very economically at a fairly inexpensive unit cost.

As required, illustrative embodiments have been disclosed herein, however the invention is not limited to the described embodiments. As will be appreciated by those skilled in the art, aspects of the invention can be variously embodied, for example, modules described herein can be combined, rearranged and variously configured, and may include hardware, software, firmware and various combinations thereof. Methods are not limited to the particular sequence described herein and may add, delete or combine various steps or operations. The invention encompasses all systems, apparatus and methods within the scope of the appended claims.

1. A circuit, comprising:
an energy storage device (ESD);
an inverter system control (ISC) circuit having a positive direct current (DC) bus and a negative DC bus, coupled to said ESD; and
a fault protection unit (FPU) configured to monitor a chassis voltage with respect to one of said DC buses.

2. The circuit of claim 1, wherein said FPU is configured to provide output that indicates whether a ground fault is detected.

3. The circuit of claim 2, wherein said FPU is configured to provide said output to an ISC circuit controller configured to terminate operation of said ISC circuit when a ground fault is detected.

4. The circuit of claim 1, wherein said FPU is configured to use said chassis voltage to check for presence of a ground fault.

5. The circuit of claim 1, wherein said FPU is configured to provide a fault signal when said chassis voltage is outside a predetermined range.

6. The circuit of claim 1, wherein said ISC circuit is coupled to at least one electric machine.

7. The circuit of claim 6, wherein said FPU is configured to detect a ground fault between said electric machine output and said chassis.

8. The circuit of claim 1, wherein said FPU is configured to detect a ground fault between at least one of said positive and negative DC buses and said chassis.

9. The circuit of claim 1, wherein said FPU is configured to detect a ground fault between an output of said ISC circuit and said chassis.

10. A fault protection unit (FPU), comprising:
a fault detection portion configured to monitor a chassis voltage with respect to a direct current (DC) bus (V_{CH-DC}) and use said chassis voltage to determine whether a fault is present; and
wherein said FPU is configured to provide status output that indicates results of said check.

11. The FPU of claim 10, wherein said fault detection portion is configured to compare said chassis voltage V_{CH-DC} to at least one reference voltage.

12. The FPU of claim 10, wherein said fault detection portion is configured to determine whether said chassis voltage V_{CH-DC} is within a predetermined range.

13. The FPU of claim 12, further comprising a voltage divider configured to attenuate a voltage at said DC bus.

14. The FPU of claim 10, further comprising a status output portion configured to receive said fault detection portion output and provide said status output.

15. The FPU of claim 15, wherein said status output portion comprises a signal transmitter.

16. The FPU of claim 16, wherein said signal transmitter is configured to provide electrical isolation between its input and its output.

17. A method, comprising:
monitoring a chassis voltage with respect to a DC bus (V_{CH-DC});
using said chassis voltage to determine whether a ground fault exists; and
providing status output that indicates results of said check.

18. The method of claim 17, wherein said using said chassis voltage to check for presence of a ground fault comprises comparing said chassis voltage to at least one reference voltage.

19. The method of claim 18, wherein said providing status output comprises providing a fault signal when said ground fault is detected.

20. The method of claim 17, wherein said providing status output comprises providing output from a signal transmitter.
